(19) United States
(12) Patent Application Publication
(10) Pub. No.: US 2001/0026487 A1
(43) Pub. Date: Oct. 4, 2001

(54) Apparatus and method for controlling access to a memory system for electronic equipment

(75) Inventor: Yuichi Koga, Tokyo (JP)

Correspondence Address: Finnegan, Henderson, Farabow,, Garrett & Dunner, L.L.P., 1300 I Street, N.W., Washington, DC, 20005-3315, US

(73) Assignee: Kabushiki Kaisha

(21) Appl. No.: 09/808,367

(22) Filed: Mar. 15, 2001

(30) Foreign Application Priority Data
Mar. 16, 2000 (JP) P2000-073414

(51) Int. Cl. G11C 7/00

(52) U.S. Cl. 365/202

(57) ABSTRACT

A memory system is provided for electronic equipment having a plurality of memory modules. The plurality of memory modules are coupled in series to allow operation at higher operating frequencies by avoiding signal reflections at branch points between the memory modules and the memory controller. The plurality of memory modules include both on-board type memory modules and slot type memory modules, to minimize increase in the installation area for the plurality of memory modules. Also provided is a method for controlling start-up operation of the electronic equipment using the memory system.

### BACKGROUND OF THE INVENTION

1. Field of the Invention

The present invention relates to an apparatus and method for controlling access to a memory system comprising a plurality of memory modules for electronic equipment. More particularly, the present invention relates to an apparatus and method for controlling access to a plurality of memory modules comprising different types of modules that are coupled to a memory controller in series, in order to achieve higher operating speed.

The widespread and diverse use of electronic equipment, and personal computers in particular, creates a strong demand to increase the data processing speed and amount of data that can be processed. Increases in data processing speed have been achieved by increasing the operating clock frequency for the central processing unit (CPU) of the electronic equipment. Further increases in data processing speed are possible by increasing the operating frequency of the installed memory modules and the data transfer bus of the electronic equipment.

The amount of data processed has been increased by adding expansion memory, in addition to the installed memory, in the electronic equipment. In the same way that a CPU has a particular operating frequency, expansion memory modules have a designated operating frequency. Conventional expansion memory modules typically have an operating frequency of 66 MHz. Recently, expansion memory modules have been developed that have an operating frequency of 100 MHz.

However, the performance of conventional expansion memory systems is limited by certain inherent design limitations, as shown in FIG. 4. FIG. 4 illustrates a conventional expansion memory system, which includes a memory controller 401 and a plurality of memory slots 402, 403, 404 for installing a plurality of memory modules that are connected to the memory controller 401 in parallel. Thus, the plurality of memory slots 402, 403, 404 contain a plurality of memory modules or cards 405, 406, 407, respectively. Since the memory modules are coupled to the memory controller 401 in parallel, as illustrated in FIG. 4, the memory bus for the conventional expansion memory system includes a plurality of connecting branch points B1, B2 between the memory controller 401 and each expansion memory module.

Consequently, when a plurality of memory modules having an operating frequency of 100 MHz are installed in the slots to increase the data processing speed, noises are generated by signal reflections at the connecting branch points of the memory bus. These noises interfere with normal operation of the computer system. Thus, the architecture of a conventional memory system limits the operating speed.

FIG. 5 illustrates an alternative memory system architecture that eliminates the problem of noise generated by signal reflections at the connecting branch points. The memory system shown in FIG. 5 uses a plurality of memory module slots that are connected to the memory controller in series. Thus, this memory system architecture can realize a higher speed of operation by eliminating the branch points of the memory bus that generate the undesired reflections.

In FIG. 5, the memory controller 501 is connected to a first expansion memory slot 502. The first expansion memory slot 502 is connected to a second expansion memory slot 503. Similarly, the second expansion memory slot 503 is connected to a third expansion memory slot 504. Thus, the plurality of memory slots is connected in series to the memory controller. Finally, the third expansion memory slot 504 is connected to a terminator 508 to prevent signal reflections. Each memory slot accepts one of expansion memory modules 505, 506, and 507.

One such memory module system, that achieves higher operating speed by chaining a plurality of expansion memory slots in series, has been introduced as the RAMBUS® DRAM by RAMBUS®, Inc. However, the RAMBUS® memory system architecture has a different limitation that makes it undesirable for small electronic equipment, especially for personal computers. As illustrated in FIG. 5, the memory architecture incorporates only slot-type memory modules. Thus, all of the memory modules must be installed in slots on a board in the electronic equipment. Consequently, the RAMBUS® architecture requires a significant increase in installation area to provide the plurality of memory slots in the electronic equipment. The increase of the installation area to provide the plurality of slots is extremely undesirable for small electronic equipment, especially for personal computers.

Instead of exclusively using memory slots, it is preferable to decrease the installation area by installing a memory module directly on the board. Hereinafter, a memory module that is installed directly on the board is referred to as an on-board type memory module and a memory module that is installed in a memory slot is referred to as a slot-type memory module.

Since the on-board type memory module is installed directly on the board during the manufacture of the electronic equipment, it is impossible for a user to change it even if there are defects in the on-board type memory module. Consequently, if the memory architecture uses only on-board type memory modules, a user cannot correct malfunctions in the computer system due to defects in the installed memory module.

Therefore, there is a need for a memory module system that achieves a higher operation speed by utilizing both on-board type memory modules and slot-type memory modules, to reduce the need to increase the installation area. Further, there is a need for a method for controlling access to the expansion memory modules utilizing both of the on-board type memory module and the slot type memory modules that avoids malfunctions in the computer system due to limitations of the memory modules.

### SUMMARY OF THE INVENTION

The apparatus and method of the present invention solve the aforementioned problems and overcomes the limitations of conventional memory module systems by providing a memory control apparatus and method that reliably achieve memory access control at higher operating speeds when memory modules are installed in the memory system.

According to the present invention, there is provided electronic equipment, comprising a board for receiving a plurality of memory modules, the board including an on-board memory area for installing on-board type memory modules, and a slot-type memory area for installing slot-type memory modules; at least one on-board type memory module installed in the on-board memory area, each on-board type memory module having a specified operating frequency; at least one memory slot provided in the slot-type memory area, each memory slot being coupled in series to the on-board memory module; at least one slot-type memory module, installed in the memory slot in the slot-type memory area, each slot-type memory module having a specified operating frequency; a memory controller coupled in series to the on-board memory and slot-type memory modules, the memory controller providing access using a designated operating frequency; and a memory bus that couples the memory controller to the on-board memory and slot-type memory modules in series.

There is also provided a method for controlling start-up operation of electronic equipment that includes a plurality of memory modules coupled in series, comprising the steps of providing an on-board memory area including at least one on-board type memory module in the electronic equipment; providing a slot-type memory area including at least one memory slot, each memory slot being coupled to the on-board memory in series; installing at least one slot-type memory module in the at least one memory slot; and providing a memory controller, coupled in series to the on-board memory and slot-type memory, that controls access to the on-board and slot-type memory modules.

There is also provided a method for controlling start-up operation of electronic equipment comprising the steps of providing at least one on-board type memory module and at least one slot for receiving at least one slot-type memory module, each of the on-board and slot-type memory modules having attribute information; providing at least one board for mounting the at least one on-board type memory module and the at least one slot for receiving the at least one slot-type memory module; mounting the at least one on-board type memory module on the board; determining whether one of the on-board type and slot-type memory modules is defective based on the attribute information; and controlling a start-up operation of the electronic equipment based on the determination.

Both the foregoing general description and the following detailed description are exemplary and explanatory only and do not restrict the present invention as claimed. The foregoing merely provides further explanation of the claimed invention. The accompanying drawings, which are incorporated in and constitute a part of this specification, illustrate embodiments of the present invention and, together with the description, explain the principles of the present invention.

### BRIEF DESCRIPTION OF THE DRAWINGS

FIG. 1 depicts a method for mounting a plurality of different types of memory modules in series, consistent with the present invention.

FIG. 2 depicts the main components of a personal computer system that employs the method for mounting the plurality of different types of memory modules depicted in FIG. 1.

FIG. 3 depicts steps performed for the start up operation of an embodiment of the personal computer system as depicted in FIG. 2.

FIG. 4 depicts a conventional method for mounting a plurality of memory modules in parallel for a low-speed memory system.

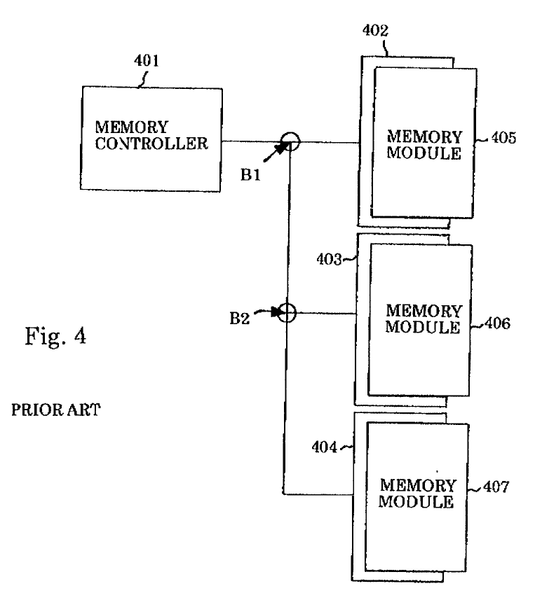

FIG. 5 depicts a conventional method for mounting a plurality of memory modules in series for a high-speed memory system.

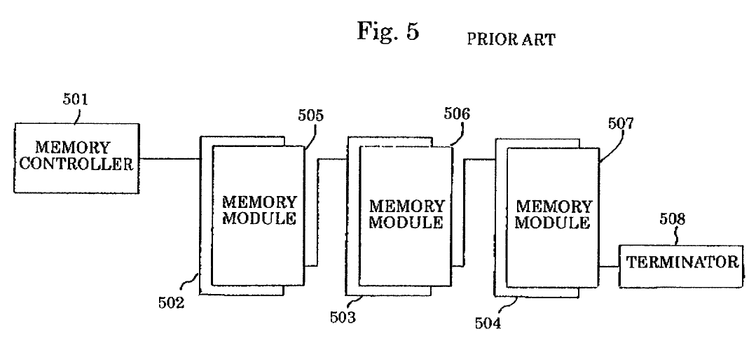

### DETAILED DESCRIPTION

Methods and systems consistent with the present invention provide a new method for mounting a plurality of memory modules of different types. This mounting method allows efficient mounting of a mixture of memory modules in a small mounting area with a low manufacturing cost.

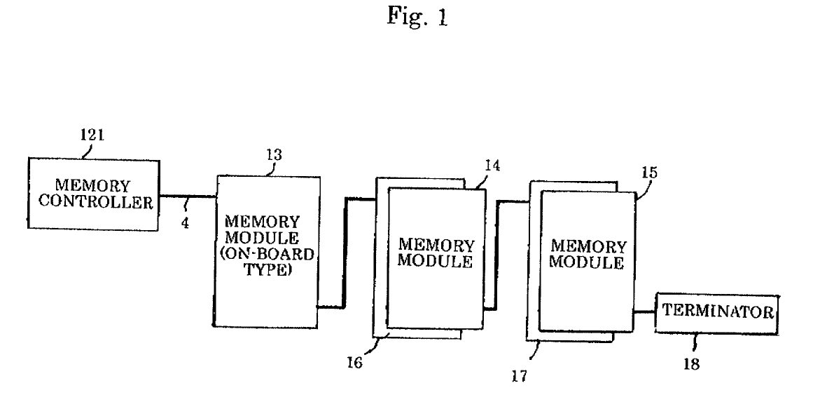

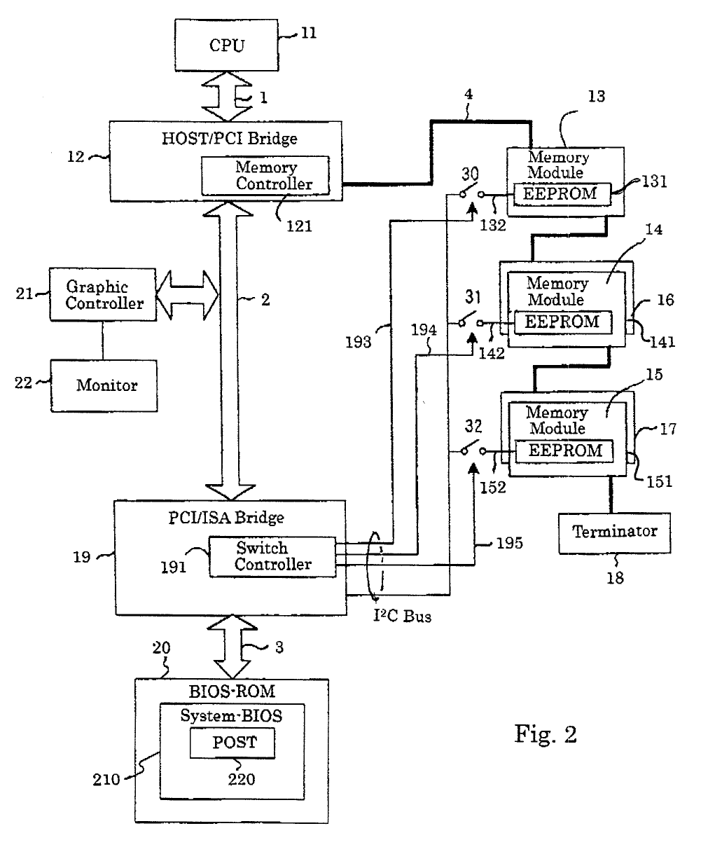

FIGS. 1 and 2 illustrate the main components of a memory control apparatus, consistent with the present invention. FIG. 1 illustrates the coupling of a plurality of discrete memory modules in series in a manner consistent with the present invention. FIG. 2 illustrates the main components of a personal computer (PC) system 10 in which the memory modules are mounted. Memory control apparatus consistent with the present invention can be implemented in a computer system, such as a laptop or notebook personal computer (PC) system or any computer system, that typically has an on-board type expansion memory module and slot-type expansion memory modules mounted in memory slots. One of skill in the art can appreciate that the computer system can provide for more or less than two slots for memory modules.

The main components of the memory control apparatus in the PC system 10 comprise a CPU 11, a HOST-PCI bridge 12, a first expansion memory module 13 mounted on a board, a second expansion memory module 14 installed in a first expansion memory slot 16, a third expansion memory module 15 installed in a second expansion memory slot 17, a terminator 18, a Peripheral Component Interconnect/Industry Standard Architecture (PCI/ISA) bridge 19, a BIOS-ROM 20, a graphic controller 21, a monitor 22, a first analog switch 30, a second analog switch 31, a third analog switch 32, a CPU (processor) bus 1, a Peripheral Component Interconnect (PCI) bus 2, an Industrial Standard Architecture (ISA) bus 3, and a memory bus 4.

The CPU 11 controls the execution of application programs, including programs on a system BIOS 210, based on an operating system (OS). The Host-PCI bridge 12 is a bridge device for bidirectionally coupling the CPU bus 1 and the PCI bus 2. The Host-PCI bridge 12 contains a memory controller 121 for controlling access to the expansion memories. The first on-board memory module 13 is installed in the nearest phase to the memory controller 121. The second and third expansion memory modules 14, 15 are respectively installed in the first and second expansion memory slots 16, 17 that are positioned at a more distant phase position than the installed position of the first on-board memory module 13 from the memory controller 121.

The expansion memory slots 16, 17 have the same connector configuration for installing both of the second and third expansion memory modules 14, 15, each of which may or may not have a different specified operating frequency with each other. For example, the memory module 14 installed in the first expansion memory slot 16 could have a specified operating frequency of 66 MHz, and the memory module 15 installed in the second expansion memory slot 17 could have a specified operating frequency of 100 MHz.

When both of the memory modules 14, 15 are installed in the respective expansion memory slots 16, 17, the first on-board memory module 13, the second memory module 14 and the third memory module 15 are coupled to the memory controller 121 in series, like a daisy chain.

The first memory module 13 is installed during the manufacture of the computer system 10. Consequently, after the completion of the manufacture, it is hard for a user to change or expand the first memory module 13. The second and third memory modules 14, 15 also are also installed in the respective expansion memory slots 16, 17 during the manufacturing process. However, it is hard for a user to replace the memory modules with other memory modules having the same or different operating frequencies.

The access control to each of the memory modules 13, 14 and 15 from the memory controller 121 can be performed through the memory bus 4. The memory bus 4 in the computer system 10 is designated so as to operate at an established operating frequency, for example, of 100 MHz. Of course, it is possible to change the designated operating frequency for the memory bus 4. In order to change the designated operating frequency for the memory bus 4, the memory controller 121 selects a desired clock signal that is generated from a clock generator (not shown) for operating the memory bus 4.

Each of the first, second and third memory modules 13, 14 and 15 comprises a plurality of chips mounted on a base plate. Further, the respective memory modules 13, 14 and 15 include electrically erasable and programmable read-only memory (EEPROM)s, 131, 141 and 151, for storing attribute information for the respective memory modules. The attribute information for each module can include the specified operating frequency, memory size, name of manufacturer, or any other type of information describing the module.

Each of the first, second and third memory modules 13, 14 and 15 includes a signal line for reading the data from each of the EEPROMs in the memory modules. As shown in FIG. 2, a data reading signal line 132 provided in the mounting unit for the first memory module 13 reads the data in the EEPROM 131 for the first memory module 13. The signal line 132 is coupled to the PCI/ISA bridge 19 through the first analog switch 30. A data reading signal line 142 provided in the first expansion memory slot 16 reads the data in the EEPROM 141 for the second memory module 14. The signal line 142 is coupled to the PCI/ISA bridge 19 through the second analog switch 31. Similarly, a data reading signal line 152 provided in the second expansion memory slot 17 reads the data in the EEPROM 151 for the third memory module 15 through the third analog switch 32. The signal line 152 is coupled to the PCI/ISA bridge 19. It is possible to use a serial bus, such as a I²C bus as the data reading signal lines 132, 142 and 152.

The ON/OFF operations of the first, second and third analog switches 30, 31 and 32 are controlled by switching signals 193, 194 and 195 from a switching control circuit 191 provided in the PCI/ISA bridge 19. Thus, the first, second and third analog switches 30, 31 and 32 are turned on/off by the switching signals 193, 194 and 195 from the switching control circuit 191 in due order. Therefore, it is possible to access the EEPROM 131 in the first memory module 13, the EEPROM 141 in the second memory module 14, and the EEPROM 151 in the third memory module 15, in order.

In the embodiment shown in FIG. 2, the data reading signal lines 132, 142 and 152 are used to read the operating frequencies of the respective memory modules from the respective EEPROMs 131, 141 and 151. The data reading signal lines 132, 142 and 152 are independent from the memory bus 4. Thus, it becomes possible to control access to the memory module even before designating the operating condition for the memory bus 4 at the operating frequency.

The PCI/ISA bridge 19 connects bi-directionally between the PCI bus 2 and the ISA bus 3. The PCI/ISA bridge 19 includes the switching control circuit 191 for controlling ON/OFF operations of the analog switches 30, 31 and 32 for accessing to the EEPROMs 131, 141 and 151 in order to read the specified operating through the I²C bus. The controls of the ON/OFF operations of the analog switches 30, 31 and 32 and the access to the EEPROMs 131, 141 and 151 are executed by a System BIOS 210 provided in the Basic I/O System (BIOS) ROM 20.

A display monitor 22 can be included in the system for displaying screens generated by the OS or the application programs. The display monitor 22 is used for displaying a warning message regarding installation of an improper memory module having a different operating frequency from the established operating frequency for the computer system. In order to display the message, the monitor is coupled to the System-BIOS through a graphic controller 21, the PCI bus 2 and the ISA bus 3. Thus, the System-BIOS 210 controls the display of a message on the monitor 22.

The BIOS-ROM 20 stores the System-BIOS 210. The BIOS-ROM 20 comprises flash memories, which are capable of writing over the programs and can be operated in real mode.

The System-BIOS 210 includes the Power-On Self Test (POST) routine 220 for self-checking normal operations of the hardware devices in the computer system when the main power switch is on or when the computer system is restarted. Further, the System-BIOS 210 includes device drivers for controlling the various I/O devices, a BIOS setup routine for establishing system environments, and the system managing programs for executing various System Management Interrupt (SMI) operations.

The POST routine 220 includes the normal hardware checking routines and initialization routines. Further, the POST routine 220 includes a checking routine for examining the specified operating frequency in the attribute information of each memory module and for displaying a message on the display monitor 22 when an improper memory module, having a specified operating frequency different from the operating frequency of the computer system, is mounted in the memory expansion slot.

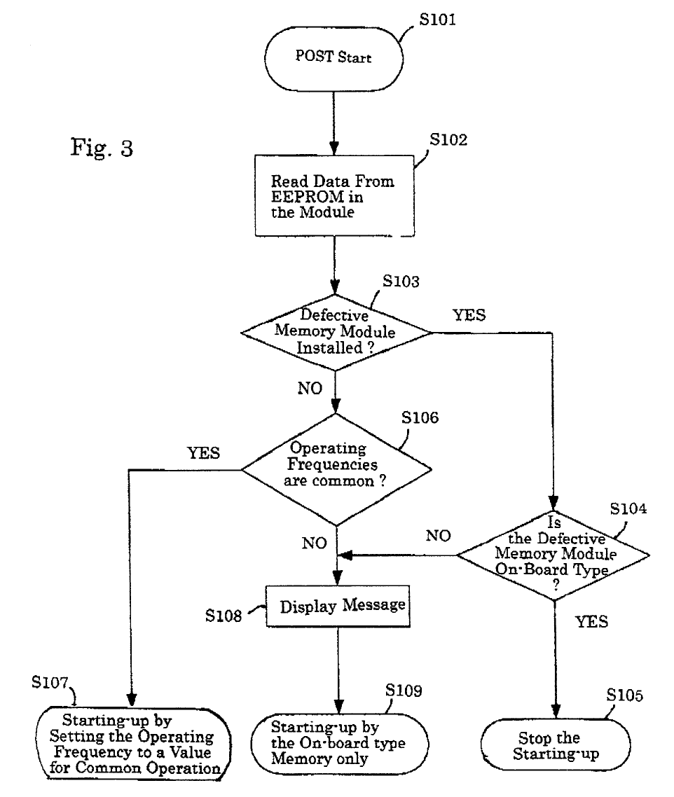

FIG. 3 depicts a flow chart of the steps of the POST operation of the computer system consistent with the present invention.

When the main power for the computer system is turned on, the system BIOS is started and the POST operation is started (Step S101).

The ON/OFF control operations for the analog switches are executed in order to access the memory modules. Thus, the first, second and third analog switches 30, 31 and 32 are cycled on and off, in turn, in order to read the attribute information in the EEPROMs 131, 141, and 151 for the memory modules 13, 14 and 15, respectively (Step S102). Reading the attribute information for each memory module gives the respective operating frequency for each memory module. Further, by examining the operating frequency attributes of the memory modules, the memory controller can detect whether a defective memory module is mixed among the first, second and third memory modules 13, 14 and 15. Thus, based on the data from the respective read operations, the System-BIOS 210 determines whether there is a defective memory module among the memory modules (Step S103).

If a defective memory module is detected among the memory modules (Step S103, Yes), the System-BIOS 210 determines whether the defective memory module is mounted on the board, i.e. an on-board type memory module 13 (Step S104). If the defective memory module is an on-board type memory module 13 (Step S104, Yes), the start up operation for the computer system is stopped (Step S105).

The reason for stopping the starting operation is that the plurality of memory modules is connected in series. In this embodiment, the on-board type memory module is first in series with the memory controller; therefore, it is impossible to assure normal operation, even if both of the slot-type memory modules are working properly. Consequently, when an on-board memory module is determined to be defective, the start-up operation for the computer system is stopped to avoid malfunctions in the computer system.

When an on-board type memory module is determined to be defective, it is also possible to display an error message on the display monitor 22 or to notify a user by a warning sound, such as a beep sound, in order to change or repair the defective memory module.

On the other hand, if the defective module is not an on-board type memory module, i.e., a slot-type memory module is determined to be the defective module (Step S104, No), the System-BIOS 210 displays a warning message on the display monitor 22 (Step S108).

After displaying the warning message, the computer system continues the start-up operation by using only on-board type memory (Step S109).

Returning to Step S103, if there are no defective memory modules (Step S103, No), then the System-BIOS 210 determines whether the operating frequencies for the respective memory modules are the same, based on the data read from the attribute information (Step S106).

If all of the operating frequencies for the respective memory modules are the same (Step S106, Yes), the computer starts normal operation by establishing the common operating frequency in the respective registers (not shown) in the respective memory modules (Step S107).

If all of the operating frequencies for the respective memory modules are not the same, i.e., some of the operating frequencies are different from each other (Step S106, No), the System-BIOS 210 displays a warning message on the display monitor (Step S108). As explained above, after displaying the warning message, the computer system enters start-up operations by using only the on-board type memory (Step S109).

As another embodiment, if all of the operating frequencies for the respective memory modules are not the same (Step S106, No), it is also possible to change the designation of the operating frequency.

For example, if the operating frequencies for the slot-type memory modules 14 and 15 are lower than the operating frequency for the on-board type memory module, and the on-board type memory module is operable at the operating frequency of the slot-type memory modules 14 and 15, two alternate operating methods are possible for the memory system.

The first method maximizes the memory capacity of the memory modules. Thus, if the operating frequency for the on-board type memory module, i.e. the first memory module 13, is higher than the operating frequency for the slot-type memory modules, the operating frequency for the on-board type memory module is set to to the lower operating frequency of the slot-type memory modules, to allow use of all the memory modules. By selecting the lower operating frequency for the memory modules, it is possible to maximize the memory capacity by ensuring that all memory modules will function properly.

The second method maximizes the operating frequency of the memory modules. When the operating frequency of the on-board type memory module is higher than the operating frequency of the slot-type memory modules, then only the on-board memory module is used. By selecting the higher operating frequency of the on-board memory module, it is possible to attain the maximum operating frequency, although the memory capacity of the system is decreased.

In order to select these designations during the start up operations, the user may select which method to use after Step S108 and before the controller continues the start-up operation.

Further, the required information, such as a preference for maximum memory capacity or an assured operating frequency, may be stored in the on-board type memory module, in the BIOS-ROM 20, eliminating the need for EEPROM 131 in memory module 13. Thus, the information for the on-board type memory module is stored in the computer system, further reducing the required mounting area and cost.

In the above-mentioned embodiments, the System-BIOS 210 executes various operations for the memory modules. However, it is also possible to execute the operations by using other firmware.

As explained above, the memory controlling apparatus controls the POST operation that determines whether there is a defective memory module among the mounted memory modules that are connected in series, as well as the on-board memory module, that is nearest in series to the memory controller.

Other embodiments of the present invention will be apparent to those skilled in the art from the consideration of the specification and practice of the invention disclosed herein. In particular, the invention is applicable to any type of electronic equipment, such as computers. It is intended that the specification and examples be considered as exemplary only, with a true scope and sprit of the invention being indicated by the following claims.

I claim:

1. Electronic equipment comprising:
a board including an on-board memory area for installing on-board type memory modules, and a slot-type memory area for installing slot-type memory modules;
at least one on-board type memory module installed in the on-board memory area, each on-board type memory module having a specified operating frequency;
at least one memory slot provided in the slot-type memory area, each memory slot being coupled in series to the on-board memory module;
at least one slot-type memory module, installed in the memory slot in the slot-type memory area, each slot-type memory module having a specified operating frequency;
a memory controller coupled in series to the on-board memory and slot-type memory modules, the memory controller providing access using a designated operating frequency; and
a memory bus that couples the memory controller to the on-board memory and slot-type memory modules in series.

2. The electronic equipment of claim 1, further comprising a frequency controller that designates the operating frequency of the memory bus.

3. The electronic equipment of claim 2, wherein the frequency controller designates the specified operating frequency of the slot-type memory module as the operating frequency for both the on-board memory and slot-type memory modules, when the operating frequency of the on-board memory module is different than the operating frequency of the slot-type memory module.

4. The electronic equipment of claim 2, wherein the frequency controller designates the specified operating frequency of the on-board memory module as the operating frequency for both the on-board memory and slot-type memory modules, when the operating frequency of the on-board memory module is different than the operating frequency of the slot-type memory module.

5. The electronic equipment of claim 2, further comprising an input mechanism for designating whether to use the specified operating frequency of the on-board memory module or the slot-type memory module, when the operating frequency of the on-board memory module is different than the operating frequency of the slot-type memory module.

6. The electronic equipment of claim 5, wherein the frequency controller designates the specified operating frequency of the slot-type memory module as the operating frequency for both the on-board memory and slot-type memory modules, when the operating frequency of the on-board memory module is different than the operating frequency of the slot-type memory module.

7. The electronic equipment of claim 5, wherein the frequency controller designates the specified operating frequency of the on-board memory module as the operating frequency for both the on-board memory and slot-type memory modules, when the operating frequency of the on-board memory module is different than the operating frequency of the slot-type memory module.

8. The electronic equipment of claim 1, further comprising notification to a user when the memory controller detects a defective one of the on-board and slot-type memory modules.

9. A method for manufacturing electronic equipment that includes a plurality of memory modules coupled in series, comprising the steps of:
providing an on-board memory area including at least one on-board type memory module in the electronic equipment;
providing a slot-type memory area including at least one memory slot, each memory slot being coupled to the on-board memory in series;
installing at least one slot-type memory module in the at least one memory slot; and
providing a memory controller, coupled in series to the on-board memory and slot-type memory, that controls access to the on-board and slot-type memory modules.

10. The method of claim 9, wherein each on-board type memory module is directly installed on a board in the electronic equipment and each slot-type memory module installed in a memory slot has attribute information; further comprising the steps of:
determining whether a defective memory module is included among the on-board and slot-type memory modules based on the attribute information of the respective on-board and slot-type memory modules; and
controlling start-up operation of the electronic equipment based on the determination.

11. A method for controlling start-up operation of electronic equipment having an on-board type memory module and a slot receiving a slot-type module, each of the on-board type and slot-type modules having attribute information, comprising the steps of:
trying to read the attribute information of the on-board type and slot-type modules;
determining whether one of the on-board type and slot-type memory modules is defective based on the attribute information; and
controlling a start-up operation of the electronic equipment based on the determination.

12. Electronic equipment, comprising:
an on-board type memory module installed on a board;
at least one memory slot provided on the board, the memory slot coupled in series to the on-board type memory module;
a memory controller, coupled in series to the on-board type memory module and the at least one memory slot.
